(19) United States
(12) Patent Application Publication
(10) Pub. No.: US 2026/0171298 A1
(43) Pub. Date: Jun. 18, 2026

(54) MULTILAYER COMMON MODE FILTER

(71) Applicant: AMOTECH CO., LTD., Incheon (KR)

(72) Inventors: Byungguk LIM, Incheon (KR); Heehwang KIM, Incheon (KR)

(73) Assignee: AMOTECH CO., LTD., Incheon (KR)

(21) Appl. No.: 19/126,912

(22) PCT Filed: Nov. 1, 2023
(86) PCT No.: PCT/KR2023/017205

§ 371 Date: May 16, 2025

(30) Foreign Application Priority Data
Nov. 2, 2022 (KR) 10-2022-0144171

(51) Int. Cl. H01F 27/28; H03H 7/01

(52) U.S. Cl. CPC H01F 27/2804; H01F 2027/2809; H03H 7/0138

(57) ABSTRACT

A multilayer common mode filter of the present disclosure has a filter stack comprising: a coil stack which includes a plurality of coils forming different channels; and a stack which is stacked underneath the coil stack and has a capacitor pattern, a floating pattern, an inductor pattern, and a ground pattern, wherein resonant frequency characteristics may vary according to the inductor pattern.

### TECHNICAL FIELD

The present disclosure relates to a multilayer common mode filter that allows signal current in a differential mode to pass through and removes noise current in a common mode in an electronic device to which a high-speed signal line is applied.

### BACKGROUND ART

Generally, mobile terminals adopt the Mobile Industry Processor Interface (MIPI) D-PHY standard as a digital data transmission standard. The MIPI D-PHY standard is a digital data transmission standard that connects a main circuit of a mobile terminal to a display or camera, and refers to a method of transmitting data using a differential signal with two transmission lines.

With the rapid increase in the volume of data transmitted and received within mobile terminals, a transmission method capable of transmitting and receiving data at a higher speed than the MIPI D-PHY standard is required for mobile terminals.

Accordingly, recent research in the mobile terminal industry has been conducted on applying the MIPI C-PHY standard to mobile terminals. The MIPI C-PHY standard employs three transmission lines, transmitting different voltages to the respective transmission lines from a transmitting side and performing differential output on a receiving side by taking differences between the lines.

The contents described in the Background Art are to aid in understanding the background of the disclosure, and may include contents that are not related to disclosed conventional technology.

### SUMMARY OF INVENTION

### Technical Problem

The present disclosure is proposed in consideration of the circumstances, and an object of the present disclosure is to provide a multilayer common mode filter in which a stack including a capacitor pattern, a floating pattern, an inductor pattern, and a ground pattern is disposed under a filter stack, thereby enabling control of characteristics such as a resonance point (resonant frequency) and cutoff.

Furthermore, another object of the present disclosure is to provide a multilayer common mode filter in which a plurality of via conductors, each including via holes for connecting coil patterns, are arranged without overlapping one another, thereby preventing defects occurring during a stacking process, and enabling adjustment of filter characteristics.

### Solution to Problem

To achieve the above object, a multilayer common mode filter according to an embodiment of the present disclosure may include a first stack provided with a plurality of coil patterns, a second stack provided with a plurality of coil patterns, and disposed under the first stack, and a third stack disposed under the second stack. The third stack may include a plurality of capacitor patterns disposed under the second stack, a floating pattern disposed under the plurality of capacitor patterns, and configured to form additional capacitance by overlapping with the plurality of capacitor patterns, a ground pattern disposed under the floating pattern, and an inductor pattern disposed between the floating pattern and the ground pattern. A first end of the inductor pattern may be connected to the floating pattern, and a second end of the inductor pattern may be connected to the ground pattern.

Each of the first stack, the second stack, and the third stack may be a low temperature co-fired ceramic stack.

The first stack may include a first coil pattern, a second coil pattern, and a third coil pattern. The second stack may include a fourth coil pattern, a fifth coil pattern, and a sixth coil pattern. The first stack and the second stack may form a coil stack. The coil stack may be configured such that the first coil pattern, the second coil pattern, the third coil pattern, the fourth coil pattern, the fifth coil pattern, and the sixth coil pattern are sequentially stacked. The first coil pattern and the sixth coil pattern may form a first coil that forms a first channel. The second coil pattern and the third coil pattern may be interposed between the first coil pattern and the sixth coil pattern, and form a second coil that forms a second channel. The fourth coil pattern and the fifth coil pattern may be interposed between the third coil pattern and the sixth coil pattern, and form a third coil that forms a third channel.

The first stack may include a first sheet, a first terminal pattern placed on a first surface of the first sheet, a second terminal pattern placed on the first surface of the first sheet, and spaced apart from the first terminal pattern, a second sheet disposed under the first sheet, a first coil pattern forming a first loop that has a rectangular shape and is wound on a first surface of the second sheet, the first coil pattern including a first end positioned in an inner peripheral region of the first loop and connected to the first terminal pattern through a via hole passing through the first sheet, and a second end positioned in an outer peripheral region of the first loop, a third sheet disposed under the second sheet, a second coil pattern forming a second loop that has a rectangular shape and is wound on a first surface of the third sheet, the second coil pattern including a first end positioned in an inner peripheral region of the second loop and connected to the second terminal pattern through a via hole passing through the first sheet and the second sheet, and a second end positioned in an outer peripheral region of the second loop, a fourth sheet disposed under the third sheet, and a third coil pattern forming a third loop that has a rectangular shape and is wound on a first surface of the fourth sheet, the third coil pattern including a first end positioned in an inner peripheral region of the third loop and connected to the second end of the second coil pattern through a via hole passing through the third sheet, and a second end positioned in an outer peripheral region of the third loop.

The second stack may include a fifth sheet, a fourth coil pattern forming a fourth loop that has a rectangular shape and is wound on a first surface of the fifth sheet, the fourth coil pattern including a first end positioned in an inner peripheral region of the fourth loop, and a second end positioned in an outer peripheral region of the fourth loop, a sixth sheet disposed under the fifth sheet, a fifth coil pattern forming a fifth loop that has a rectangular shape and is wound on a first surface of the sixth sheet, the fifth coil pattern including a first end positioned in an inner peripheral region of the fifth loop and connected to the first end of the fourth coil pattern through a via hole passing through the fifth sheet, and a second end positioned in an outer peripheral region of the fifth loop, a seventh sheet disposed under the sixth sheet, a sixth coil pattern forming a sixth loop wound on a first surface of the seventh sheet, the sixth coil pattern including a first end positioned in an inner peripheral region of the sixth loop, and a second end positioned in an outer peripheral region of the sixth loop, an eighth sheet disposed under the seventh sheet, a third terminal pattern placed on the first surface of the seventh sheet, and including a first end connected to the first end of the fourth coil pattern and the first end of the fifth coil pattern through a via hole passing through the fifth sheet, the sixth sheet, and the seventh sheet, and a fourth terminal pattern placed on the first surface of the seventh sheet and spaced apart from the third terminal pattern, the fourth terminal pattern including a first end connected to the first end of the sixth coil pattern through a via hole passing through the seventh sheet.

The third stack may include a ninth sheet, a plurality of capacitor patterns placed on a first surface of the ninth sheet and spaced apart from each other, a tenth sheet disposed under the ninth sheet, a floating pattern placed on a first surface of the tenth sheet, and forming a plurality of overlapping areas by overlapping with the plurality of capacitor patterns, the floating pattern being configured to form additional capacitance in the plurality of overlapping regions, an eleventh sheet disposed under the tenth sheet, an inductor pattern forming a seventh loop wound on the first surface of the tenth sheet, the inductor pattern including a first end positioned in an inner peripheral region of the seventh loop and connected to the floating pattern, a twelfth sheet disposed under the eleventh sheet, and a ground pattern disposed on a first surface of the twelfth sheet, and connected to a second end of the inductor pattern.

The inductor pattern may include a first region overlapping the ground pattern, and a second region not overlapping the ground pattern.

A filter stack formed by stacking the first stack, the second stack, and the third stack may have a first resonant frequency, and a second resonant frequency higher than the first resonant frequency. The second resonant frequency may shift to a higher frequency as a length of the inductor pattern increases. The second resonant frequency may shift to a lower frequency as a length of the inductor pattern decreases.

A filter stack formed by stacking the first stack, the second stack, and the third stack may include a first side surface, a second side surface opposite to the first side surface, a third side surface, and a fourth side surface opposite to the third side surface. The multilayer common mode filter further according to an embodiment of the present disclosure may include a first external electrode disposed on the first side surface, and connected to a second end of a first coil pattern, a second end of a sixth coil pattern, and a third end of a first capacitor pattern that are exposed to the first side surface, a second external electrode disposed on the first side surface, and connected to a second end of a second coil pattern, a second end of a third coil pattern, and a second end of a second capacitor pattern that are exposed to the first side surface, a third external electrode disposed on the first side surface, and connected to a second end of a fourth coil pattern, a second end of a fifth coil pattern, and a second end of a third capacitor pattern that are exposed to the first side surface, a fourth external electrode disposed on the second side surface, and connected to a second end of a first terminal pattern, a second end of a fourth terminal pattern, and a second end of a fourth capacitor pattern that are exposed to the second side surface, a fifth external electrode disposed on the second side surface, and connected to a second end of a third terminal pattern and a second end of a fifth capacitor pattern that are exposed to the second side surface, a sixth external electrode disposed on the second side surface, and connected to a second end of a second terminal pattern and a second end of a sixth capacitor pattern that are exposed to the second side surface, a seventh external electrode disposed on the third surface, and connected to a first end of a ground pattern that is exposed to the third side surface, and an eighth external electrode disposed on the fourth side surface, and connected to a second end of the ground pattern that is exposed to the fourth side surface.

### Advantageous Effects of Invention

According to the present disclosure, a multilayer common mode filter has an effect of allowing a distance (spacing) between coil patterns forming each channel to be kept constant, thereby enabling resistance and inductance of the coil patterns forming each channel to remain uniform.

Furthermore, the multilayer common mode filter has an effect of minimizing changes in inductance characteristics and common mode attenuation characteristics of the coil patterns by disposing terminal patterns for connection with external electrodes in uppermost and lowermost portions of a filter stack.

In addition, the multilayer common mode filter has an effect of expanding an attenuation band by forming an additional notch in common mode attenuation characteristics through placement of a capacitor pattern and a floating pattern below a coil stack.

Additionally, the multilayer common mode filter has an effect of achieving broadband characteristics by forming an additional pole (i.e., additional capacitance) through the capacitor pattern and the floating pattern, along with a pole formed by the coil patterns of an electrode stack.

Furthermore, the multilayer common mode filter has an effect of minimizing variations in the inductance characteristics of the coil patterns by forming a constant distance (spacing) between the channels.

In addition, the multilayer common mode filter has an effect of enhancing magnetic coupling (i.e., electromagnetic coupling) among first to third coils and minimizing the degradation of a differential signal.

Additionally, the multilayer common mode filter has an effect of simplifying a manufacturing process because the electrode stack can be formed by stacking sheets in which two or fewer via holes are formed.

That is, in the multilayer common mode filter, the terminal patterns are disposed in uppermost and lowermost portions of the electrode stack, a second coil pattern and a third coil pattern of a second channel are placed between a first coil pattern and a sixth coil pattern of a first channel, and a fourth coil pattern and a fifth coil pattern of a third channel are placed between the third coil pattern and the sixth coil pattern. Accordingly, the number of via holes required to connect the coil patterns may be minimized, and two or fewer via holes are formed in each sheet.

Furthermore, the multilayer common mode filter has an effect of increasing capacitance, without adding an electrode layer that includes a coil pattern or increasing the area of the coil pattern, thereby achieving a greater capacitance than conventional multilayer common mode filters within the same size.

Furthermore, the multilayer common mode filter has an effect of readily adjusting and controlling the second resonant frequency because a short path circuit formed of the floating pattern, the inductor pattern, and a ground pattern is configured through a third stack disposed under the coil stack.

In addition, the multilayer common mode filter has an effect of enabling adjustment of a distance between a first resonant frequency and a second resonant frequency by placing or removing a magnetic sheet in or from the lowermost portion of the filter stack.

Furthermore, the multilayer common mode filter has an effect of preventing pressure from being concentrated in regions, where via conductors are located, during a stacking process by dispersing pressure through distributed arrangement of the via conductors in a non-overlapping manner.

Furthermore, the multilayer common mode filter has an effect of preventing cracks from being formed in a stack during the stacking process, as the pressure applied to the stack is dispersed during the stacking process through the distributed arrangement of the via conductors.

In addition, the multilayer common mode filter has an effect of preventing short-circuit occurrence by avoiding electrode compression caused by pressure concentration, as the pressure applied to the stack during the stacking process can be dispersed through the distributed arrangement of the via conductors.

Additionally, the multilayer common mode filter has an effect of enabling the flattening of a surface of the stack by preventing the formation of irregularities between a via conductor region and a surrounding region during the stacking process through the distributed arrangement of the via conductors.

Furthermore, the multilayer common mode filter does not include a magnetic layer, thereby preventing losses caused by a magnetic base material and enhancing the common mode attenuation characteristic at a first resonance point.

Furthermore, the multilayer common mode filter does not include a magnetic layer, thereby preventing losses caused by a magnetic base material and enhancing the common mode attenuation characteristic at a first resonance point.

In addition, the multilayer common mode filter has an effect of satisfying cutoff frequency characteristics required in the industrial market by reducing insertion loss between two channels compared to a conventional multilayer common mode filter.

Furthermore, because the multilayer common mode filter is configured using a low temperature co-fired ceramic stack that does not include a magnetic layer, the multilayer common mode filter has an effect of increasing common mode impedance at a primary resonance point F compared to a conventional multilayer common mode filter.

### BRIEF DESCRIPTION OF DRAWINGS

FIG. 1 is a perspective view of a multilayer common mode filter according to an embodiment of the present disclosure.

FIG. 2 is an exploded perspective view for describing a filter stack in FIG. 1.

FIG. 3 is an exploded perspective view for describing a first stack in FIG. 2.

FIG. 4 is a diagram for describing a first sheet in FIG. 3.

FIG. 5 is a diagram for describing a second sheet in FIG. 3.

FIG. 6 is a diagram for describing a third sheet in FIG. 3.

FIG. 7 is a diagram for describing a fourth sheet in FIG. 3.

FIG. 8 is an exploded perspective view for describing a second stack in FIG. 2.

FIG. 9 is a diagram for describing a fifth sheet in FIG. 8.

FIG. 10 is a diagram for describing a sixth sheet in FIG. 8.

FIG. 11 is a diagram for describing a seventh sheet in FIG. 8.

FIG. 12 is a diagram for describing an eighth sheet in FIG. 8.

FIG. 13 is a sectional view showing a vertical cross-section of a coil stack in FIG. 2.

FIG. 14 is an exploded perspective view for describing a third stack in FIG. 2.

FIG. 15 is a diagram for describing a ninth sheet in FIG. 14.

FIG. 16 is a diagram for describing a tenth sheet in FIG. 14.

FIG. 17 is a diagram for describing an eleventh sheet in FIG. 14.

FIG. 18 is a diagram for describing a twelfth sheet of FIG. 14.

FIG. 19 is a diagram showing an equivalent circuit of a multilayer common mode filter according to an embodiment of the present disclosure.

FIG. 20 is a diagram for comparing common mode attenuation characteristics between a multilayer common mode filter according to an embodiment of the present disclosure and a conventional multilayer common mode filter.

FIG. 21 is a diagram for comparing insertion loss characteristics between a multilayer common mode filter according to an embodiment of the present disclosure and a conventional multilayer common mode filter.

FIG. 22 is a diagram for comparing common mode impedance characteristics between a multilayer common mode filter according to an embodiment of the present disclosure and a conventional multilayer common mode filter.

### DESCRIPTION OF EMBODIMENTS

Hereinafter, embodiments of the present disclosure will be described in detail with reference to the attached drawings.

Embodiments are provided to explain the present disclosure more fully to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of embodiments, when it is described that each layer (film), area, pattern, or structure is formed “on” or “under” each substrate, layer (film), area, pad, or pattern, this includes both expressions, including that a layer is formed on another layer “directly” or “with an additional layer interposed between the two layers (indirectly)”. Furthermore, the criterion for “on” or “under” of each layer is based on the drawings.

The drawings are provided solely to aid in understanding the spirit of the present disclosure and should not be interpreted as limiting the scope of the present disclosure. Furthermore, in the drawings, relative thickness, length, or size may be exaggerated for convenience and clarity of description.

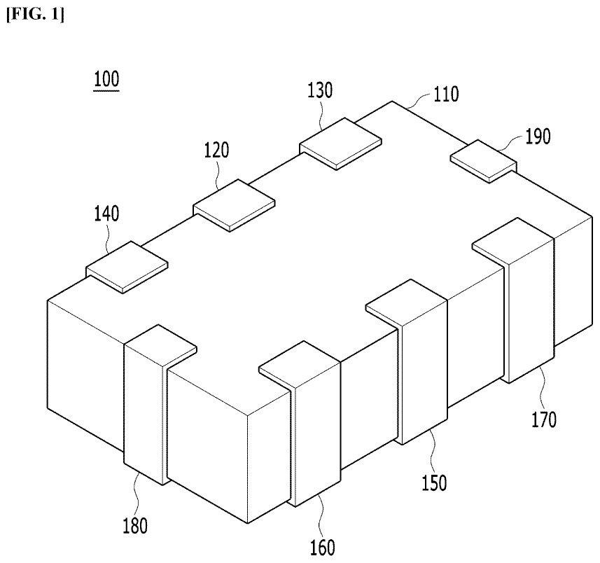

Referring to FIG. 1, a multilayer common mode filter 100 according to an embodiment of the present disclosure includes a filter stack 110, a first external electrode 120, a second external electrode 130, a third external electrode 140, a fourth external electrode 150, a fifth external electrode 160, a sixth external electrode 170, a seventh external electrode 180, and an eighth external electrode 190. Hereinafter, the multilayer common mode filter 100 operating as a three-channel C-PHY common mode filter will be described as an example.

The filter stack 110 is a stack in which sheets, on which six coil patterns forming three channels, a capacitor pattern for adjusting characteristics such as a resonant frequency, a floating pattern, inductor patterns, and a ground pattern are arranged, are stacked. The multilayer common mode filter 100 adjusts resonance point (resonant frequency) shift, cutoff characteristics, and the like through the capacitor pattern and a floating pattern that form capacitance, inductor patterns constituting inductance, and a ground pattern forming a ground.

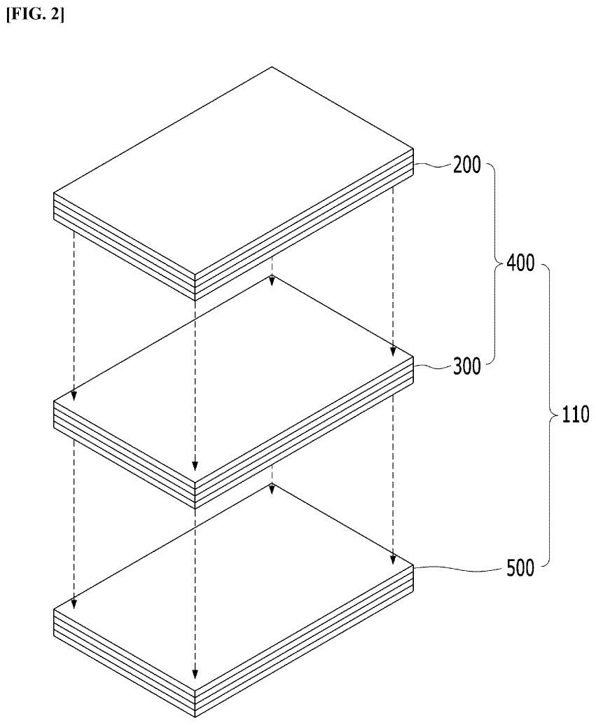

Referring to FIG. 2, the filter stack 110 includes a first stack 200, a second stack 300 disposed under the first stack 200, and a third stack 500 disposed under the second stack 300.

The first stack 200 is formed by stacking a plurality of sheets on which metal patterns are formed.

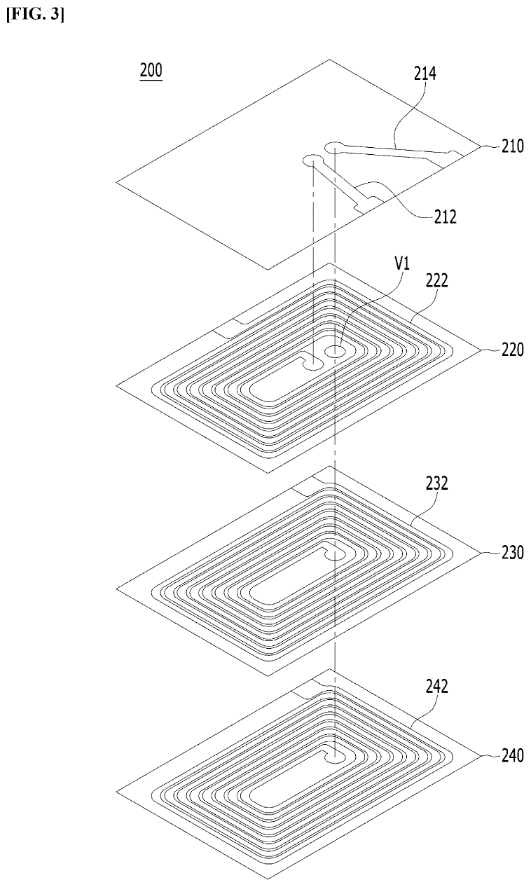

For example, referring to FIG. 3, the first stack 200 includes a first sheet 210, a second sheet 220 disposed under the first sheet 210, a third sheet 230 disposed under the second sheet 220, and a fourth sheet 240 disposed under the third sheet 230. Each of the first to fourth sheets 210 to 240 is a sheet made of a ceramic material.

Here, a first terminal pattern 212 and a second terminal pattern 214 are formed on the first sheet 210. A first coil pattern 222 is formed on the second sheet 220. A second coil pattern 232 is formed in the third sheet 230. A third coil pattern 242 is formed in the fourth sheet 240.

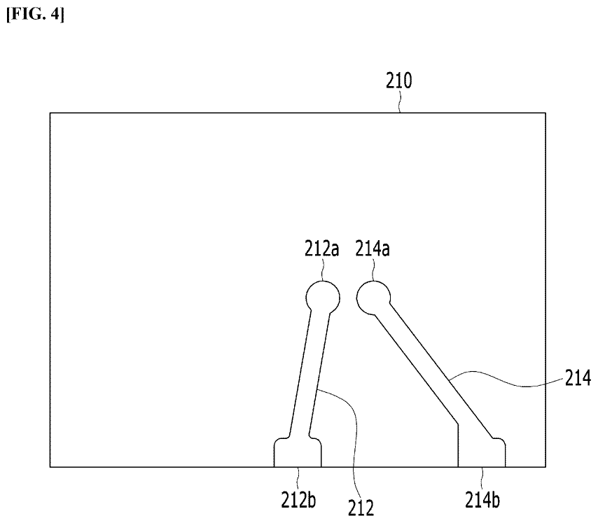

Referring to FIG. 4, the first terminal pattern 212 and the second terminal pattern 214 for connecting coil patterns 222, 232, and 242 of the first stack 200 to external electrodes are formed on the first sheet 210.

The first terminal pattern 212 is placed on an upper surface of the first sheet 210. A first end 212a of the first terminal pattern 212 is disposed adjacent to a center of the first sheet 210.

A second end 212b of the first terminal pattern 212 is disposed to be aligned with a first side of the first sheet 210. Accordingly, the second end 212b of the first terminal pattern 212 is exposed to a second side surface of the filter stack 110, and connected to the fourth external electrode 150.

The second terminal pattern 214 is placed on the upper surface of the first sheet 210 so as to be spaced apart from the first terminal pattern 212. The second terminal pattern 214 is disposed between the first terminal pattern 212 and a fourth side of the first sheet 210, and is disposed to be biased toward the fourth side of the first sheet 210.

A first end 214a of the second terminal pattern 214 is disposed adjacent to the center of the first sheet 210. The first end 214a of the second terminal pattern 214 is spaced apart from the first end 212a of the first terminal pattern 212 by a predetermined distance.

A second end 214b of the second terminal pattern 214 is disposed to be aligned with the second side of the first sheet 210. Accordingly, the second end 214b of the second terminal pattern 214 is spaced apart from the second end 212b of the first terminal pattern 212 by a predetermined distance, and is exposed to the second side surface of the filter stack 110, and connected to the sixth external electrode 170.

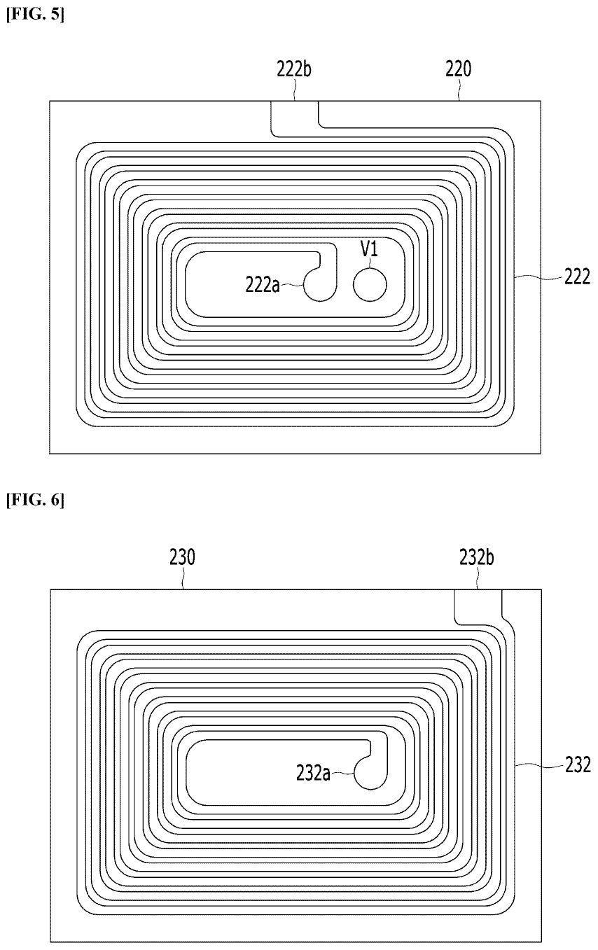

Referring to FIG. 5, the second sheet 220 is disposed under the first sheet 210. A first via hole V1 and a first coil pattern 221 that forms a first channel are disposed in the second sheet 220.

The first coil pattern 222 is placed on an upper surface of the second sheet 220. The first coil pattern 222 is wound multiple times on the upper surface of the second sheet 220, thus forming a first loop. The first coil pattern 222 is wound multiple times around a virtual winding axis passing through a center of the second sheet 220 to form the first loop. As an example, the first coil pattern 222 forms the first loop having a rectangular shape.

A first end 222a of the first coil pattern 222 is disposed in an inner peripheral region of the first loop, and positioned adjacent to the center of the second sheet 220. The first end 222a of the first coil pattern 222 is connected to the first end 212a of the first terminal pattern 212 through a vial hole.

A second end 222b of the first coil pattern 222 is disposed in an outer peripheral region of the first loop, and disposed to be aligned with a first side of the second sheet 220. Accordingly, the second end 222b of the first coil pattern 222 is exposed to a first side surface of the filter stack 110, and connected to the first external electrode 120.

The first via hole V1 is disposed so as to be adjacent to the center of the second sheet 220 and to be spaced apart from the first end 222a of the first coil pattern 222. The first via hole V1 is disposed opposite to the center of the second sheet 220 with the first end 222a of the first coil pattern 222 interposed therebetween.

The first via hole V1 is formed to penetrate through the second sheet 220. An upper portion of the first via hole V1 is connected to the second terminal pattern 214. A lower portion of the first via hole V1 is connected to the second coil pattern 232 and the third coil pattern 242 that are formed in the third sheet 230, which will be described below.

Referring to FIG. 6, the third sheet 230 is disposed under the second sheet 220. A second coil pattern 232 that forms a second channel is disposed in the third sheet 230.

The second coil pattern 232 is placed on an upper surface of the third sheet 230. The second coil pattern 232 is wound multiple times on the upper surface of the third sheet 230, thus forming a second loop. The second coil pattern 232 is wound multiple times around a virtual winding axis passing through a center of the third sheet 230 to form the second loop. As an example, the second coil pattern 232 forms the second loop having a rectangular shape.

A first end 232a of the second coil pattern 232 is disposed in an inner peripheral region of the second loop, and positioned adjacent to the center of the third sheet 230. The first end 232a of the second coil pattern 232 is connected to the first end 214a of the second terminal pattern 214 through the first via hole V1 of the second sheet 220.

A second end 232b of the second coil pattern 232 is disposed in an outer peripheral region of the second loop, and disposed to be aligned with a first side of the third sheet 230. The second end 232b of the second coil pattern 232 is disposed to be spaced apart from the second end 222b of the first coil pattern 222 by a predetermined distance, and is exposed to the first side surface of the filter stack 110, and connected to the second external electrode 130.

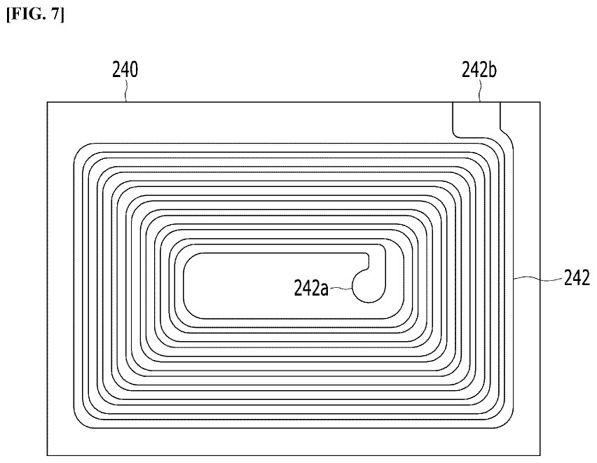

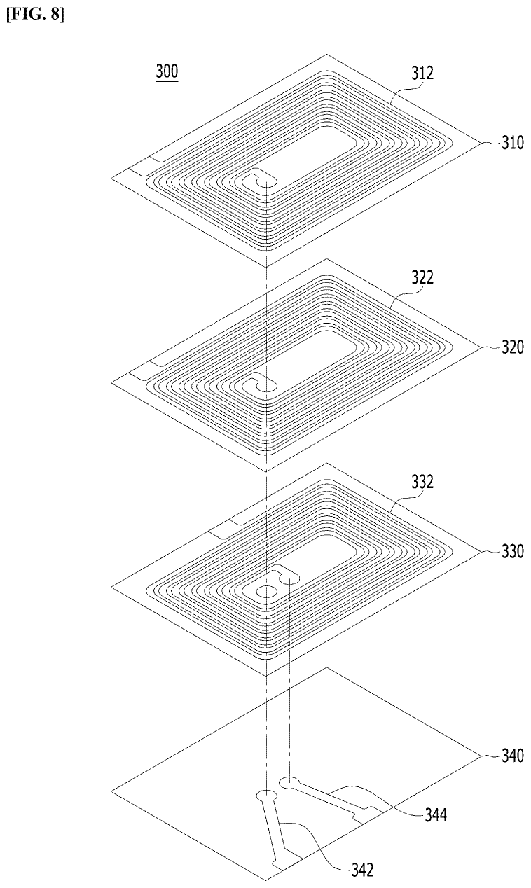

Referring to FIG. 7, the fourth sheet 240 is disposed under the third sheet 230. A third coil pattern 242 that forms the second channel along with the second coil pattern 232 is disposed in the fourth sheet 240.

The third coil pattern 242 is placed on an upper surface of the fourth sheet 240. The third coil pattern 242 is wound multiple times on the upper surface of the fourth sheet 240, thus forming a third loop. The third coil pattern 242 is wound multiple times around a virtual winding axis passing through the center of the fourth sheet 240 to form the third loop. As an example, the third coil pattern 242 forms the third loop having a rectangular shape.

A first end 242a of the third coil pattern 242 is disposed in an inner peripheral region of the third loop, and positioned adjacent to a center of the fourth sheet 240. The first end 242a of the third coil pattern 242 is connected to the first end 232a of the second coil pattern 232 through a via hole, and connected to the first end 214a of the second terminal pattern 214 through the first via hole V1 of the second sheet 220.

A second end 242b of the third coil pattern 242 is disposed in an outer peripheral region of the third loop, and disposed to be aligned with a first side of the fourth sheet 240. Accordingly, the second end 242b of the third coil pattern 242 is disposed to be spaced apart from the second end 222b of the first coil pattern 222 by a predetermined distance

The second end 242b of the third coil pattern 242 is disposed to be aligned with the second end 232b of the second coil pattern 232, and is exposed to the first side surface of the filter stack 110 to be connected to the second external electrode 120 along with the second end 232b of the second coil pattern 232.

The second stack 300 is disposed under the first stack 200, and formed by stacking a plurality of sheets on which metal patterns are formed.

For example, referring to FIG. 8, the second stack 300 includes a fifth sheet 310, a sixth sheet 320 disposed under the fifth sheet 310, a seventh sheet 330 disposed under the sixth sheet 320, and an eighth sheet 340 disposed under the seventh sheet 330. Each of the fifth to eighth sheets 310 to 340 is a sheet made of a ceramic material.

A fourth coil pattern 312 is formed on the fifth sheet 310. A fifth coil pattern 322 is formed on the sixth sheet 320. A sixth coil pattern 332 is formed on the seventh sheet 330. A third terminal pattern 342 and a fourth terminal pattern 344 are formed on the eighth sheet 340.

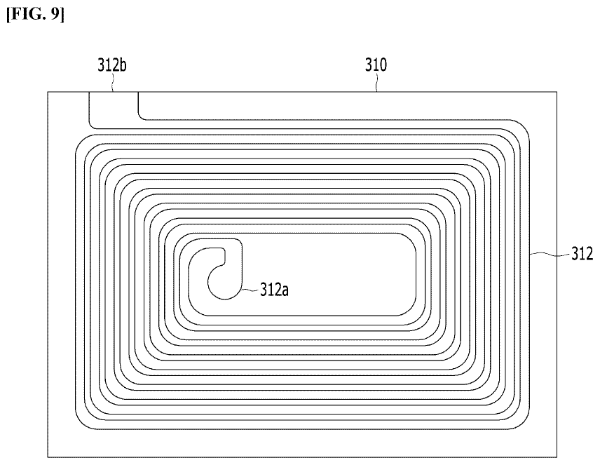

Referring to FIG. 9, the fifth sheet 310 is disposed under the fourth sheet 240, and the fourth coil pattern 312 that forms a third channel is disposed on the fifth sheet 310.

The fourth coil pattern 312 is placed on an upper surface of the fifth sheet 310. The fourth coil pattern 312 is wound multiple times on the upper surface of the fifth sheet 310, thus forming a fourth loop. The fourth coil pattern 312 is wound multiple times around a virtual winding axis passing through a center of the fifth sheet 310 to form the fourth loop. As an example, the fourth coil pattern 312 forms the fourth loop having a rectangular shape.

A first end 312a of the fourth coil pattern 312 is disposed in an inner peripheral region of the fourth loop, and positioned adjacent to the center of the fifth sheet 310. The first end 312a of the fourth coil pattern 312 is connected to a first end 322a of a fifth coil pattern 322, which will be described below, through a vial hole.

A second end 312b of the fourth coil pattern 312 is disposed in an outer peripheral region of the fourth loop, and disposed to be aligned with a first side of the fifth sheet 310. The second end 312b of the fourth coil pattern 312 is exposed to the first side surface of the filter stack 110, and connected to the third external electrode 140.

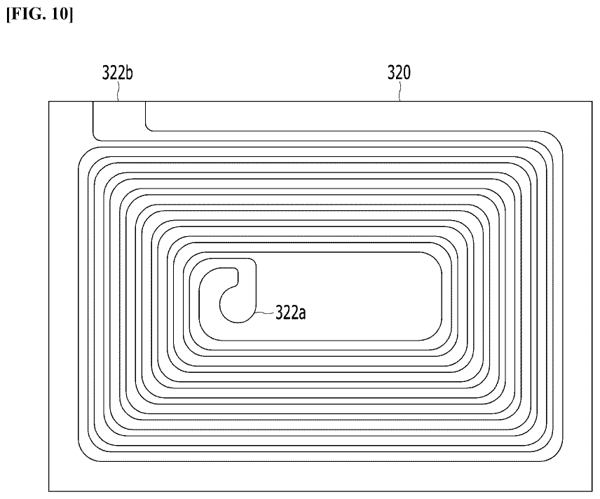

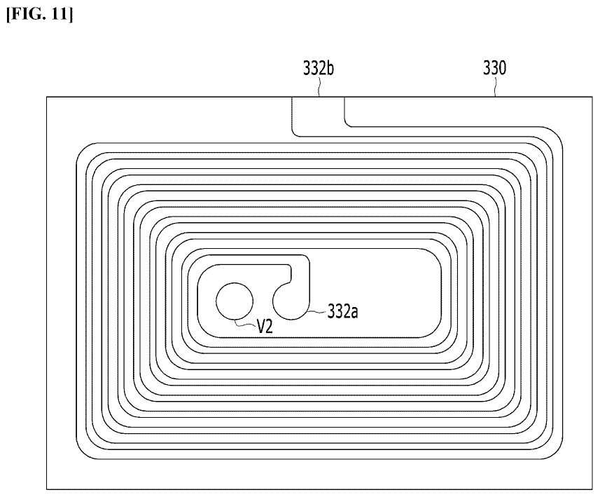

Referring to FIG. 10, the sixth sheet 320 is disposed under the fifth sheet 310. The fifth coil pattern 322 that forms the third channel along with the fourth coil pattern 312 is disposed on the sixth sheet 320.

The fifth coil pattern 322 is placed on an upper surface of the sixth sheet 320. The fifth coil pattern 322 is wound multiple times on the upper surface of the sixth sheet 320, thus forming a fifth loop. The fifth coil pattern 322 is wound multiple times around a virtual winding axis passing through a center of the sixth sheet 320 to form the fifth loop. As an example, the fifth coil pattern 322 forms the fifth loop having a rectangular shape.

A first end 322a of the fifth coil pattern 322 is disposed in an inner peripheral region of the fifth loop, and positioned adjacent to the center of the sixth sheet 320. The first end 322a of the fifth coil pattern 322 is connected to the first end 312a of the fourth coil pattern 312 through a vial hole.

A second end 322b of the fifth coil pattern 322 is disposed in an outer peripheral region of the fifth loop, and disposed to be aligned with a first side of the sixth sheet 320. The second end 322b of the fifth coil pattern 322 is aligned with the second end 312b of the fourth coil pattern 312, and is exposed to the first side surface of the filter stack 110 to be connected to the third external electrode 140 along with the second end 312b of the fourth coil pattern 312.

Referring to FIG. 11, the seventh sheet 330 is disposed under the sixth sheet 320. A second via hole V2 and a sixth coil pattern 332 that forms the first channel along with the first coil pattern 222 of the first stack 200 are formed in the seventh sheet 330.

The sixth coil pattern 332 is placed on an upper surface of the seventh sheet 330. The sixth coil pattern 332 is wound multiple times on the upper surface of the seventh sheet 330, thus forming a sixth loop. The sixth coil pattern 332 is wound multiple times around a virtual winding axis passing through a center of the seventh sheet 330 to form the sixth loop. As an example, the sixth coil pattern 332 forms the sixth loop having a rectangular shape.

A first end 332a of the sixth coil pattern 332 is disposed in an inner peripheral region of the sixth loop, and positioned adjacent to the center of the seventh sheet 330. The first end 332a of the sixth coil pattern 332 is connected to the fourth terminal pattern 344 formed on the eighth sheet 340, which will be described below, through a vial hole.

A second end 332b of the sixth coil pattern 332 is disposed in an outer peripheral region of the sixth loop, and disposed to be aligned with a first side of the seventh sheet 330. The second end 332b of the sixth coil pattern 332 is disposed to be spaced apart from the second end 312b of the fourth coil pattern 312 and the second end 322b of the fifth coil pattern 322 by predetermined distances, and is exposed to the first side surface of the filter stack 110 to be connected to the first external electrode 120.

The second via hole V2 is disposed so as to be adjacent to the center of the seventh sheet 330 and to be spaced apart from the first end 332a of the sixth coil pattern 332. The second via hole V2 is located opposite to the center of the seventh sheet 330 with the first end 332a of the sixth coil pattern 332 interposed therebetween.

The second via hole V2 is formed to penetrate through the seventh sheet 330. An upper portion of the second via hole V2 is connected to the first end 312a of the fourth coil pattern 312 and the first end 322a of the fifth coil pattern 322. A lower portion of the second via hole V2 is connected to a third terminal pattern 342 formed in the eighth sheet 340, which will be described below.

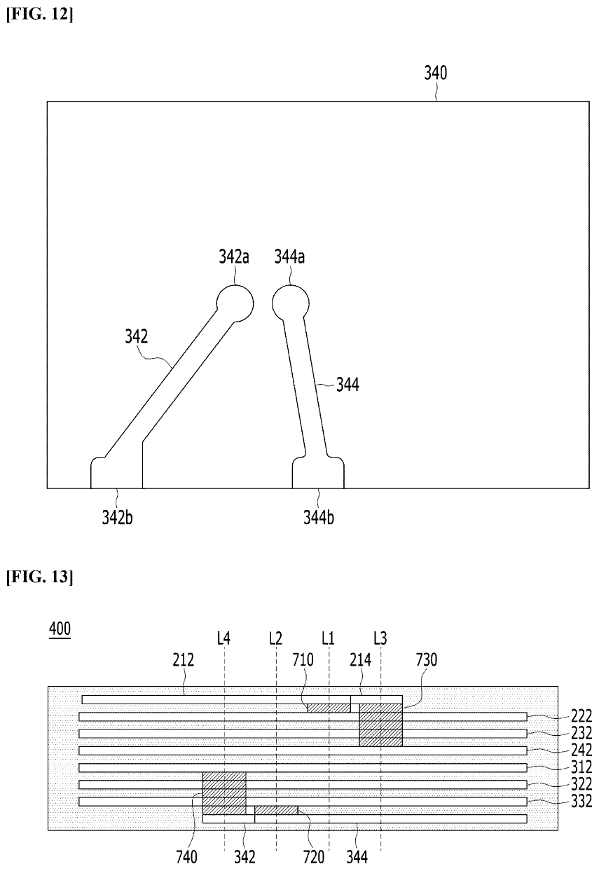

Referring to FIG. 12, the third terminal pattern 342 and a fourth terminal pattern 344 for connecting coil patterns of a second electrode layer to external electrodes are formed in the eighth sheet 340.

The third terminal pattern 342 is placed on an upper surface of the eighth sheet 340. A first end 342a of the third terminal pattern 342 is disposed adjacent to a center of the eighth sheet 340. The first end 342a of the third terminal pattern 342 is connected to the first end 312a of the fourth coil pattern 312 and the first end 322a of the fifth coil pattern 322 through the second via hole V2.

A second end 342b of the third terminal pattern 342 is disposed to be aligned with a second side of the eighth sheet 340. Accordingly, the second end 342b of the third terminal pattern 342 is exposed to the second side surface of the filter stack 110, and connected to the fifth external electrode 160.

The fourth terminal pattern 344 is placed on the upper surface of the eighth sheet 340 so as to be spaced apart from the third terminal pattern 342. A first end 344a of the fourth terminal pattern 344 is connected to the first end 332a of the sixth coil pattern 332 through a vial hole. A first end 344a of the fourth terminal pattern 344 is disposed adjacent to the center of the eighth sheet 340. The first end 344a of the fourth terminal pattern 344 is spaced apart from the first end 342a of the third terminal pattern 342 by a predetermined distance.

A second end 344b of the fourth terminal pattern 344 is disposed to be aligned with the second side of the eighth sheet 344. Accordingly, the second end 344b of the fourth terminal pattern 344 is spaced apart from the second end 342b of the third terminal pattern 342 by a predetermined distance, and is exposed to the second side surface of the filter stack 110 to be connected to the fourth external electrode 150 along with the second end 212b of the first terminal pattern 212.

The first stack 200 and the second stack 300 form a coil stack 400 that includes coils forming three channels.

The coil stack 400 is configured such that the first coil pattern 222, the second coil pattern 232, the third coil pattern 242, the fourth coil pattern 312, the fifth coil pattern 322, and the sixth coil pattern 332 are sequentially stacked.

Here, the first coil pattern 222 and the sixth coil pattern 332 form a first coil, which is a series inductor constituting the first channel. The second coil pattern 232 and the third coil pattern 242 form a second coil, which is a series inductor constituting the second channel. The fourth coil pattern 312 and the fifth coil pattern 322 form a third coil, which is a series inductor constituting the third channel.

Thus, the coil stack 400 forms a stack in which a coil pattern of the first channel, a coil pattern of the second channel, a coil pattern of the second channel, a coil pattern of the third channel, a coil pattern of the third channel, and a coil pattern of the first channel are sequentially disposed (stacked).

Accordingly, in the multilayer common mode filter 100 according to an embodiment of the present disclosure, a distance (spacing) between the coil patterns forming each channel may be kept constant, thereby enabling resistance and inductance of the coil patterns forming each channel to remain uniform.

Furthermore, the multilayer common mode filter 100 according to an embodiment of the present disclosure may minimize changes in inductance characteristics and common mode attenuation characteristics of the coil patterns by placing the terminal patterns for connection with the external electrodes in uppermost and lowermost portions of the coil stack 400. In the case where the terminal patterns are disposed in only one of the uppermost or lowermost portions, the inductance characteristics of each channel change, or the inductance characteristics of each coil pattern change, resulting in changes in the common mode attenuation characteristics.

In the multilayer common mode filter 100 according to an embodiment of the present disclosure, the terminal patterns are disposed in the uppermost and lowermost portions of the coil stack 400, the second coil pattern 232 and the third coil pattern 242 of the second channel are disposed between the first coil pattern 222 and the sixth coil pattern 332 of the first channel, and the fourth coil pattern 312 and the fifth coil pattern 322 of the third channel are disposed between the third coil pattern 242 and the sixth coil pattern 332. As a result, the number of via holes required for connecting the coil patterns may be minimized. The multilayer common mode filter 100 according to an embodiment of the present disclosure has two or fewer via holes formed in each sheet.

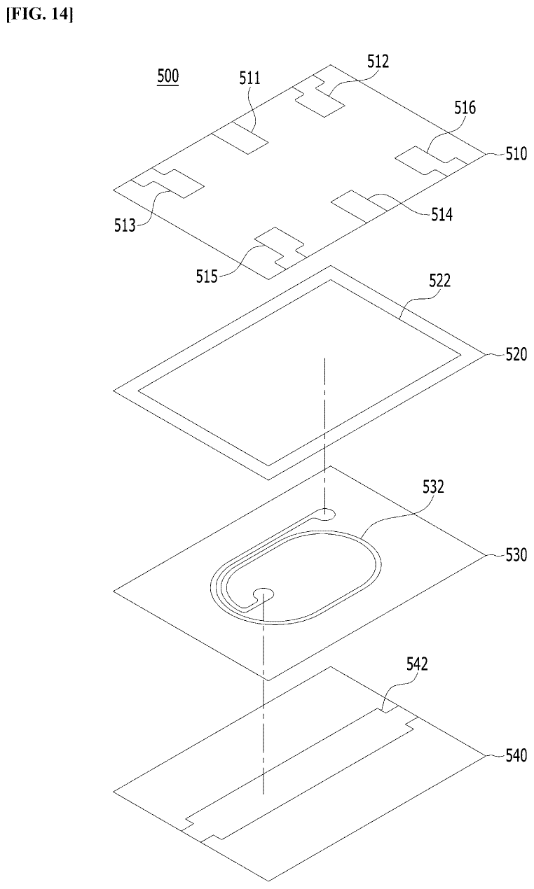

Referring to FIG. 13, the first coil pattern 222 and the sixth coil pattern 332 are interposed in the coil stack 400, and are respectively disposed adjacent to the upper and lower portions of the coil stack 400, thus forming the first channel. The second coil pattern 232 and the third coil pattern 242 are interposed in the coil stack 400, and are disposed (stacked) parallel to each other between the first coil pattern 222 and the sixth coil pattern 332, thus forming the second channel. The fourth coil pattern 312 and the fifth coil pattern 322 are interposed in the coil stack 400, and are disposed (stacked) parallel to each other between the third coil and the sixth coil, thus forming the third channel.

Accordingly, the multilayer common mode filter 100 according to an embodiment of the present disclosure may be configured such that distances (spacing) between the first channel and the second channel, the second channel and the third channel, and the third channel and the first channel are maintained constant.

In addition, the multilayer common mode filter 100 according to an embodiment of the present disclosure can minimize changes in the inductance characteristics of the coil patterns by maintaining the constant distances (spacing) between the channels.

Furthermore, in the multilayer common mode filter 100 according to an embodiment of the present disclosure, since the terminal patterns that connect the coil patterns to the external electrodes are disposed in the uppermost and lowermost portions of the filter stack 110, the distances between the coil patterns and the terminal patterns can be made identical for all channels, thereby ensuring uniform resistance and inductance of the coil patterns that form each channel.

Additionally, the multilayer common mode filter 100 according to an embodiment of the present disclosure may enhance magnetic coupling (i.e., electromagnetic coupling) among the first to third coils and minimize the degradation of a differential signal.

The coil stack 110 is configured such that a plurality of via conductors, which are formed through the via holes provided to connect the coil patterns and the terminal patterns, are arranged without overlapping one another.

For example, a first via conductor 710 is formed through a via hole that connects the first terminal pattern 212 and the first coil pattern 222.

The second via conductor 720 is formed through a via hole that connects the fourth terminal pattern 344 and the sixth coil pattern 332, and is spaced apart from the first via conductor 710 without overlapping in a plan view of the coil stack 400.

A third via conductor 730 is formed through via holes that connect the second terminal pattern 214, the second coil pattern 232, and the third coil pattern 242, and is spaced apart from the first via conductor 710 and the second via conductor 720 without overlapping in the plan view of the coil stack 400.

A fourth via conductor 740 is formed through via holes that connect the third terminal pattern 342, the fourth coil pattern 312, and the fifth coil pattern 322, and is spaced apart from the first to third via conductors 710 to 730 without overlapping in the plan view of the coil stack 400.

In other terms, a first virtual line L1 is defined as a line that penetrates through both the upper and lower surfaces of the coil stack 400 and passes through a center of the first via conductor 710 in a vertical cross-sectional view of the coil stack 400.

A second virtual line L2 is defined as a line that penetrates through both the upper and lower surfaces of the coil stack 400 in the diagram and passes through a center of the second via conductor 720 in the vertical cross-sectional view of the coil stack 400. The second virtual line L2 is spaced apart from the first virtual line L1 by a predetermined distance and is parallel to the first virtual line L1.

A third virtual line L3 is defined as a line that penetrates through both the upper and lower surfaces of the coil stack 400 in the diagram and passes through a center of the third via conductor 730 in the vertical cross-sectional view of the coil stack 400. The third virtual line L3 is positioned opposite to the first virtual line L1 with the second virtual line L2 interposed therebetween, is spaced apart from the first virtual line L1 and the second virtual line L2 by predetermined distances, and is parallel to the first virtual line L1 and the second virtual line L2.

A fourth virtual line L4 is defined as a line that penetrates through both the upper and lower surfaces of the coil stack 400 and passes through a center of the fourth via conductor 740 in the drawing. The fourth virtual line L4 is positioned opposite to the second virtual line L2 with the first virtual line L1 interposed therebetween, is spaced apart from the second virtual line L2 and the third virtual line L3 by predetermined distances, and is parallel to the first to third virtual lines L1 to L3.

As such, the multilayer common mode filter 100 according to an embodiment of the present disclosure can prevent pressure from being concentrated in regions, where via conductors are located, during a stacking process by dispersing pressure through distributed arrangement of the via conductors in a non-overlapping manner.

Furthermore, the multilayer common mode filter 100 according to an embodiment of the present disclosure can prevent cracks from being formed in a stack during the stacking process, as the pressure applied to the stack is dispersed during the stacking process through the distributed arrangement of the via conductors.

Moreover, the multilayer common mode filter 100 according to an embodiment of the present disclosure enables the prevention of short-circuit occurrence by avoiding electrode compression caused by pressure concentration, as the pressure applied to the stack during the stacking process is dispersed through the distributed arrangement of the via conductors.

Additionally, the multilayer common mode filter 100 according to an embodiment of the present disclosure enables flattening of the surface of the stack by preventing the formation of irregularities between a via conductor region and a surrounding region during the stacking process through the distributed arrangement of the via conductors.

The third stack 500 is disposed under the second stack 300. The third stack 500 is formed by stacking a plurality of sheets on which metal patterns are formed. For example, referring to FIG. 14, the third stack 500 includes a ninth sheet 510, a tenth sheet 520 disposed under the ninth sheet 510, an eleventh sheet 530 disposed under the tenth sheet 520, and a twelfth sheet 540 disposed under the eleventh sheet 530. Each of the ninth to twelfth sheets 410 to 440 is a sheet made of a ceramic material.

Metal patterns 511 to 516 and 522 for forming capacitance are formed on the ninth sheet 510 and the tenth sheet 520. A metal pattern 532 for forming inductance is formed on the eleventh sheet 530. A metal pattern 542 for forming the ground is formed on the twelfth sheet 540.

The ninth sheet 510 is disposed under the eighth sheet 340. A plurality of capacitor patterns are placed on an upper surface of the ninth sheet 510. The capacitor patterns may be configured as multiple patterns disposed on an input terminal and an output terminal of the multilayer common mode filter 100.

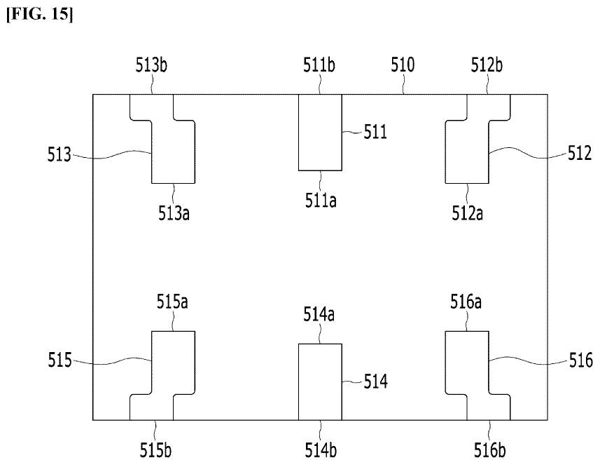

For example, referring to FIG. 15, the capacitor patterns include a first capacitor pattern 511, a second capacitor pattern 512, a third capacitor pattern 513, a fourth capacitor pattern 514, a fifth capacitor pattern 515, and a sixth capacitor pattern 516.

The first capacitor pattern 511 is placed on the upper surface of the ninth sheet 510.

A first end 511a of the first capacitor pattern 511 is disposed adjacent to a center of the ninth sheet 510.

A second end 511b of the first capacitor pattern 511 is disposed to be aligned with a first side of the ninth sheet 510. The first capacitor pattern 511 is exposed to the first side surface of the filter stack 110, and connected to the first external electrode 120.

The second capacitor pattern 512 is placed on the upper surface of the ninth sheet 510 so as to be spaced apart from the first capacitor pattern 511. The second capacitor pattern 512 is spaced apart from the first capacitor pattern 511, and is disposed to be biased toward a fourth side of the ninth sheet 510.

A first end 512a of the second capacitor pattern 512 is disposed adjacent to the center of the ninth sheet 510. A second end 512b of the second capacitor pattern 512 is disposed to be aligned with the first side of the ninth sheet 510. The second capacitor pattern 512 is exposed to the first side surface of the filter stack 110, and connected to the second external electrode 130.

The third capacitor pattern 513 is placed on the upper surface of the ninth sheet 510. The third capacitor pattern 513 is spaced apart from the first capacitor pattern 511 and the second capacitor pattern 512, and is disposed to be biased toward a third side of the ninth sheet 510. The third capacitor pattern 513 is disposed opposite to the second capacitor 512 with the first capacitor pattern 511 interposed therebetween.

A first end 513a of the third capacitor pattern 513 is disposed adjacent to the center of the ninth sheet 510. A second end 513b of the third capacitor pattern 513 is disposed to be aligned with the first side of the ninth sheet 510. The third capacitor pattern 513 is exposed to the first side surface of the filter stack 110, and connected to the third external electrode 140.

The fourth capacitor pattern 514 is placed on the upper surface of the ninth sheet 510.

A first end 514a of the fourth capacitor pattern 514 is disposed adjacent to the center of the ninth sheet 510. The first end 514a of the fourth capacitor pattern 514 faces the first end 511a of the first capacitor pattern 511.

A second end 514b of the fourth capacitor pattern 514 is disposed to be aligned with a second side of the ninth sheet 510. The fourth capacitor pattern 514 is exposed to the second side surface of the filter stack 110, and connected to the fourth external electrode 150.

The fifth capacitor pattern 515 is placed on the upper surface of the ninth sheet 510. The fifth capacitor pattern 515 is spaced apart from the fourth capacitor pattern 514, and is disposed to be biased toward the third side of the ninth sheet 510.

A first end 515a of the fifth capacitor pattern 515 is disposed adjacent to the center of the ninth sheet 510. The first end 515a of the fifth capacitor pattern 515 faces the first end 513a of the third capacitor pattern 513.

A second end 515b of the fifth capacitor pattern 515 is disposed to be aligned with the second side of the ninth sheet 510. The fifth capacitor pattern 515 is exposed to the second side surface of the filter stack 110, and connected to the fifth external electrode 160.

The sixth capacitor pattern 516 is placed on the upper surface of the ninth sheet 510. The sixth capacitor pattern 516 is spaced apart from the fourth capacitor pattern 514 and the fifth capacitor pattern 515, and is disposed to be biased toward the fourth side of the ninth sheet 510. The sixth capacitor pattern 516 is disposed opposite to the fifth capacitor pattern 515 with the fourth capacitor pattern 514 interposed therebetween.

A first end 516a of the sixth capacitor pattern 516 is disposed adjacent to the center of the ninth sheet 510. The first end 516a of the sixth capacitor pattern 516 faces the first end 512a of the second capacitor pattern 512.

A second end 516b of the sixth capacitor pattern 516 is disposed to be aligned with the second side of the ninth sheet 510. The sixth capacitor pattern 516 is exposed to the second side surface of the filter stack 110, and connected to the sixth external electrode 170.

It is assumed that the first to third external electrodes 120 to 140 disposed on the first side surface of the filter stack 110 serve as an input terminal of the multilayer common mode filter 100, and the third to sixth external electrodes 140 to 170 disposed on the second side surface of the filter stack 110 serve as an output terminal of the multilayer common mode filter 100.

The first to third capacitor patterns 511 to 513 are disposed on the first side surface of the filter stack 110 and are connected in a one-to-one manner to the first to third external electrodes 120 to 140, respectively. The fourth to sixth capacitor patterns 514 to 516 are disposed on the second side surface of the filter stack 110 and are connected in a one-to-one manner to the fourth to fifth external electrodes 150 to 160, respectively.

The filter stack 110 may include the ninth sheet 510 in which first to third capacitor patterns 511 to 513 connected to the input terminal are formed for adjusting and controlling capacitance characteristics, or the ninth sheet 510 in which fourth to sixth capacitor patterns 514 to 516 connected to the output terminal are formed.

The tenth sheet 520 is disposed under the ninth sheet 510. A floating pattern 522 for forming capacitance, along with the capacitor patterns of the ninth sheet 510, is placed on an upper surface of the tenth sheet 520.

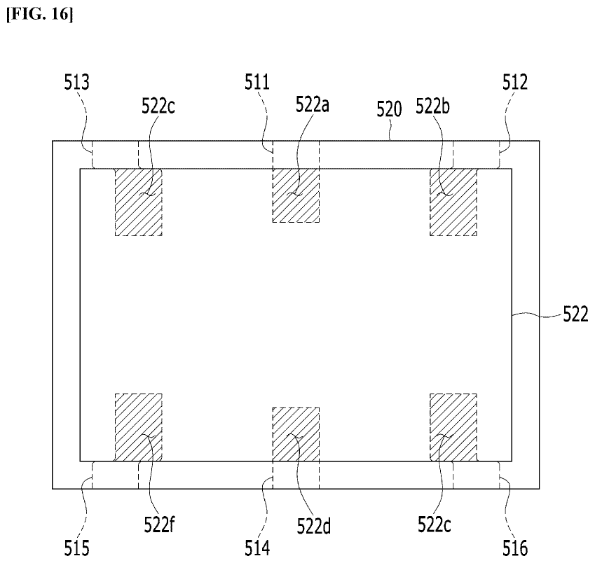

Referring to FIG. 16, the floating pattern 522 is formed in a plate shape, and placed on the upper surface of the tenth sheet 520. The floating pattern 522 has a smaller area than the tenth sheet 520, and is disposed such that an outer periphery of the floating pattern 522 is spaced apart from four sides of the tenth sheet 520. The area of the floating pattern 522 is larger than the area of an inductor pattern 532, which will be described later, and is formed to be 90% or less of the area of the tenth sheet 520.

The floating pattern 522 overlaps the capacitor patterns of the ninth sheet 510 to form an overlapping region, where capacitance is formed.

The floating pattern 522 forms a first overlapping region 522a with the first capacitor pattern 511, and forms a first capacitance in the first overlapping region 522a. The floating pattern 522 forms a second overlapping region 522b with the second capacitor pattern 512, and forms a second capacitance in the first overlapping region 522a. The floating pattern 522 forms a third overlapping region 522c with the third capacitor pattern 513, and forms a third capacitance in the third overlapping region 522c. The floating pattern 522 forms a fourth overlapping region 522d with the fourth capacitor pattern 514, and forms a fourth capacitance in the fourth overlapping region 522d. The floating pattern 522 forms a fifth overlapping region 522e with the fifth capacitor pattern 515, and forms a fifth capacitance in the fifth overlapping region 522e. The floating pattern 522 forms a sixth overlapping region 522f with the sixth capacitor pattern 516, and forms a sixth capacitance in the sixth overlapping region 522f.

As such, the floating pattern 522 forms capacitance with the capacitor patterns. Accordingly, the multilayer common mode filter 100 can expand the attenuation band by forming an additional notch in the common mode attenuation characteristics. That is, the multilayer common mode filter 100 can realize broadband characteristics by forming an additional pole due to the floating pattern 522 and the capacitor patterns, along with the pole formed by the coil patterns of the filter stack 110.

The eleventh sheet 530 is disposed under the tenth sheet 520. The inductor pattern 532 is placed on an upper surface of the eleventh sheet 530.

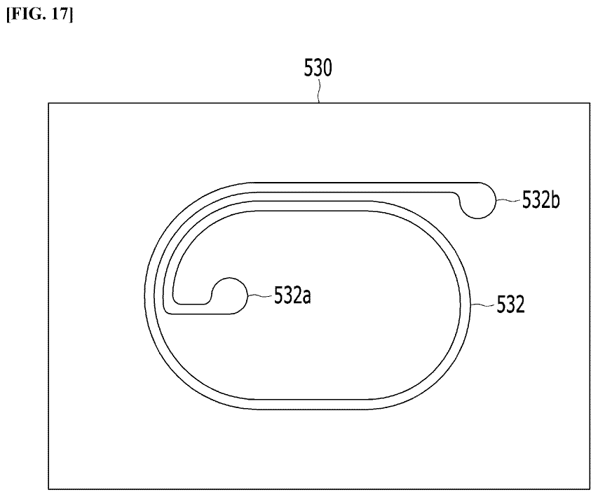

For example, referring to FIG. 17, the inductor pattern 532 is wound on the upper surface of the eleventh sheet 530, thus forming a seventh loop. The inductor pattern 532 is wound around a virtual winding axis passing through a center of the eleventh sheet 530 to form the seventh loop. The inductor pattern 532 constitutes a parallel common inductor that forms a predetermined inductance.

A first end 532a of the inductor pattern 532 is disposed in an inner peripheral region of the seventh loop, and positioned at a center of the eleventh sheet 530.

A second end 532b of the inductor pattern 532 is disposed in an outer peripheral region of the seventh loop. The second end 532b of the inductor pattern 532 is connected to the floating pattern 522 of the tenth sheet through a via hole.

The length (area) of the inductor pattern 532 may vary depending on a required secondary resonant frequency. As the length of the inductor pattern 532 increases, the inductance value increases, and the secondary resonant frequency shifts to a lower frequency. As the length of the inductor pattern 532 decreases, the inductance value decreases, and the secondary resonant frequency shifts to a higher frequency. Accordingly, the length of the inductor pattern 532 is determined based on the required secondary resonant frequency.

The inductor pattern 532 may be formed in a multi-layer structure having two or more layers. However, when configured as a multi-layer structure, the height of the multilayer common mode filter increases, and unnecessary parasitic capacitance may occur between the inductor pattern 532 and a ground pattern 542, which will be described later.

Accordingly, it is preferable that the inductor pattern 532 be formed in a single-layer structure, whereby an increase in the height of the multilayer common mode filter may be minimized, and parasitic capacitance generated between the inductor pattern 532 and the ground pattern 542 may be reduced.

The twelfth sheet 540 is disposed under the eleventh sheet 530. The ground pattern 542 is formed on the twelfth sheet 540.

The ground pattern 542 is connected to the inductor pattern 532 and reduces the influence caused by floating capacitance formed between the multilayer common mode filter 100 and the printed circuit board.

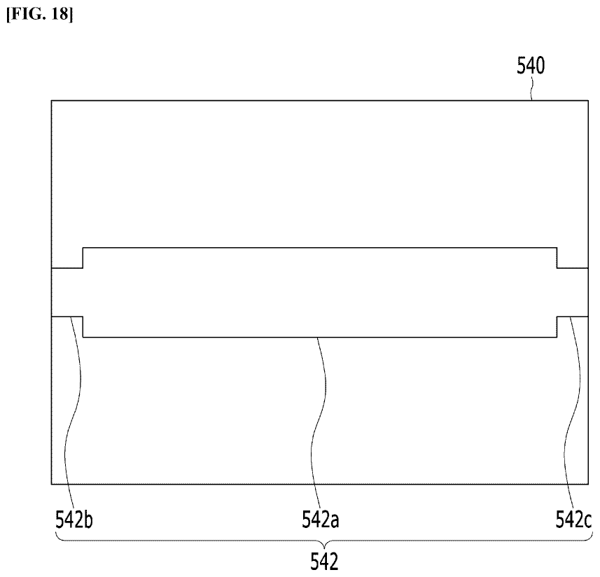

For example, referring to FIG. 18, the ground pattern 542 is formed on the upper surface of the twelfth sheet 540. The ground pattern 542 may include a first ground pattern 542a, a second ground pattern 542b, and a third ground pattern 542c.

The first ground pattern 542a is formed in a plate shape and is disposed at the center of the upper surface of the twelfth sheet 540. The first ground pattern 542a has an area smaller than that of the twelfth sheet 540, and an outer periphery of the first ground pattern 542a is disposed to be spaced apart from four sides of the twelfth sheet 540.

The first ground pattern 542a is formed in a rectangular shape having a horizontal length greater than a vertical length in the drawing. The first ground pattern 542a overlaps a portion of the inductor pattern 532, and the inductor pattern 532 has a region that does not overlap the first ground pattern 542a. In this case, the first ground pattern 542a overlaps a portion of the inductor pattern 532, thereby minimizing parasitic capacitance generated between the ground pattern 542 and the inductor pattern 532.

The first ground pattern 542a is connected to the first end 532a of the inductor pattern 532 through a via hole passing through the eleventh sheet 530.

The second ground pattern 542b extends from a third side of the first ground pattern 542a and is disposed to be aligned with a third side of the twelfth sheet 540. A first end of the second ground pattern 542b is connected to the third side of the first ground pattern 542a. A second end of the second ground pattern 542b is disposed to be aligned with the third side of the twelfth sheet 540 and is connected to the seventh external electrode 180.

The third ground pattern 542c extends from a fourth side of the first ground pattern 542a and is disposed to be aligned with a fourth side of the twelfth sheet 540. A first end of the third ground pattern 542c is connected to the fourth side of the first ground pattern 542a. A second end of the third ground pattern 542c is disposed to be aligned with the fourth side of the twelfth sheet 540 and is connected to the eighth external electrode 190.

Accordingly, the ground pattern 542 is exposed to a third side surface and a fourth side surface of the filter stack 110, thereby forming a ground connected to the seventh external electrode 180 and the eighth external electrode 190.

The first external electrode 120 is placed on the first side surface of the filter stack 110. Opposite ends of the first external electrode 120 may be formed to extend to upper and lower surfaces of the filter stack 110.

The first external electrode 120 is connected to the first coil pattern 222, the sixth coil pattern 322, and the first capacitor pattern 511 that are exposed to the first side surface of the filter stack 110. The first external electrode 120 is connected to the second end 222b of the first coil pattern 222, the second end 322b of the sixth coil pattern 322, and the second end 511b of the first capacitor pattern 511.

The second external electrode 130 is placed on the first side surface of the filter stack 110. The second external electrode 130 is disposed to be biased toward the fourth side surface of the filter stack 110, and is spaced apart from the first external electrode 120. Opposite ends of the second external electrode 130 may be formed to extend to the upper and lower surfaces of the filter stack 110.

The second external electrode 130 is connected to the second coil pattern 232, the third coil pattern 242, and the second capacitor pattern 512 that are exposed to the first side surface of the filter stack 110. The second external electrode 130 is connected to the second end 232b of the second coil pattern 232, the second end 242b of the third coil pattern 242, and the second end 512b of the second capacitor pattern 512.

The third external electrode 140 is placed on the first side surface of the filter stack 110. The third external electrode 140 is disposed to be biased toward the third side surface of the filter stack 110, and is spaced apart from the first external electrode 120. The third external electrode 140 is opposite to the second external electrode 130 with the first external electrode 120 interposed therebetween. Opposite ends of the third external electrode 140 may be formed to extend to the upper and lower surfaces of the filter stack 110.

The third external electrode 140 is connected to the fourth coil pattern 312, the fifth coil pattern 322, and the third capacitor pattern 513 that are exposed to the first side surface of the filter stack 110. The third external electrode 140 is connected to the second end 312b of the fourth coil pattern 312, the second end 322b of the fifth coil pattern 322, and the second end 513b of the third capacitor pattern 513.

The fourth external electrode 150 is placed on the second side surface of the filter stack 110. The fourth external electrode 150 is opposite to the first external electrode 120 with the filter stack 110 interposed therebetween, and is disposed to face the first external electrode 120. Opposite ends of the fourth external electrode 150 may be formed to extend to the upper and lower surfaces of the filter stack 110.

The fourth external electrode 150 is connected to the first terminal pattern 212, the fourth terminal pattern 344, and the fourth capacitor pattern 514 that are exposed to the second side surface of the filter stack 110. The fourth external electrode 150 is connected to the second end 212b of the first terminal pattern 212, the second end 344b of the fourth terminal pattern 344, and the second end 514b of the fourth capacitor pattern 514.

The fifth external electrode 160 is placed on the second side surface of the filter stack 110. The fifth external electrode 160 is opposite to the third external electrode 140 with the filter stack 110 interposed therebetween, and is disposed to face the third external electrode 140. The fifth external electrode 160 is disposed to be biased toward the third side surface of the filter stack 110, and is spaced apart from the fourth external electrode 150. Opposite ends of the fifth external electrode 160 may be formed to extend to the upper and lower surfaces of the filter stack 110.

The fifth external electrode 160 is connected to the third terminal pattern 342 and the fifth capacitor pattern 515 that are exposed to the second side surface of the filter stack 110. The fifth external electrode 160 is connected to the second end 342b of the third terminal pattern 342 and the second end 515b of the fifth capacitor pattern 515.

The sixth external electrode 170 is placed on the second side surface of the filter stack 110. The sixth external electrode 170 is opposite to the second external electrode 130 with the filter stack 110 interposed therebetween, and is disposed to face the second external electrode 130. The sixth external electrode 170 is disposed to be biased toward the fourth side surface of the filter stack 110, and is spaced apart from the fourth external electrode 150. The sixth external electrode 170 is opposite to the fifth external electrode 160 with the fourth external electrode 150 interposed therebetween. Opposite ends of the sixth external electrode 170 may be formed to extend to the upper and lower surfaces of the filter stack 110.

The sixth external electrode 170 is connected to the second terminal pattern 214 and the sixth capacitor pattern 516 that are exposed to the second side surface of the filter stack 110. The sixth external electrode 170 is connected to the second end 214b of the second terminal pattern 214 and the second end 516b of the sixth capacitor pattern 516.

The seventh external electrode 180 is placed on the third side surface of the filter stack 110. The seventh external electrode 180 is connected to the ground pattern 555 exposed to the third side surface of the filter stack 110. The seventh external electrode 180 is connected to the second end of the second ground pattern 555b exposed to the third side surface of the filter stack 110. Opposite ends of the seventh external electrode 180 may be formed to extend to the upper and lower surfaces of the filter stack 110.

The eighth external electrode 190 is placed on the fourth side surface of the filter stack 110. The eighth external electrode 190 is opposite to the eighth external electrode 190 with the filter stack 110 interposed therebetween. The eighth external electrode 190 is connected to the ground pattern 555 exposed to the third side surface of the filter stack 110. The eighth external electrode 190 is connected to the second end of the third ground pattern 555c exposed to the fourth side surface of the filter stack 110. Opposite ends of the eighth external electrode 190 may be formed to extend to the upper and lower surfaces of the filter stack 110.

The first external electrode 120 and the fourth external electrode 150 function as an input terminal and an output terminal of the first channel, which is formed by the first coil pattern 222 and the sixth coil pattern 332. The second external electrode 130 and the sixth external electrode 170 function as an input terminal and an output terminal of the second channel, which is formed by the second coil pattern 232 and the third coil pattern 242. The third external electrode 130 and the fifth external electrode 160 function as an input terminal and an output terminal of the third channel, which is formed by the fourth coil pattern 312 and the fifth coil pattern 322. The seventh external electrode 180 and the seventh external electrode 180 are connected to the ground pattern 555, thus functioning as a ground terminal.

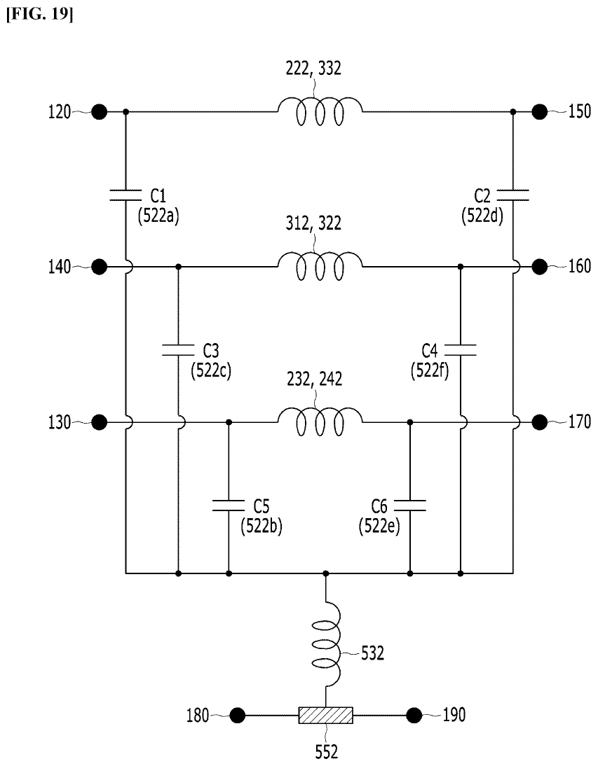

Referring to FIG. 19 illustrating an equivalent circuit of the multilayer common mode filter 100 according to an embodiment of the present disclosure, capacitance is formed between the first coil and the second coil, between the second coil and the third coil, and between the first coil and the third coil.

The filter stack 110 is formed in such a way that the coil stack 400 is formed by stacking the first stack 20 and the second stack 300 on which the coil patterns are formed, and the third stack 500, which includes the capacitor patterns, the floating pattern 522, and the inductor patterns 532 and 542, is placed under the coil stack 400.

Accordingly, the capacitor patterns connected between the coils of the respective channel and the external electrodes are interconnected, and a coupling effect is induced between the capacitor patterns and the floating pattern 522. As a result, additional capacitances C1 to C6 are formed between the coils of the respective channels and the external electrodes due to the capacitor patterns and the floating pattern 522.

Consequently, the multilayer common mode filter 100 according to an embodiment of the present disclosure can have increased capacitance without the need to add an electrode layer including a coil pattern or increase the area of the coil patterns, thereby achieving greater capacitance than a conventional multilayer common mode filter 10 while maintaining the same size.

Furthermore, in the multilayer common mode filter 100 according to an embodiment of the present disclosure, as additional capacitance is formed by the capacitor pattern and the floating pattern 522, an additional notch can be formed in the common mode attenuation characteristics, thereby expanding the attenuation band.

The opposite ends of the inductor pattern 532 are connected to the floating pattern 522 and the ground pattern 555, respectively, and constitute a short circuit between the floating pattern 522 and the ground pattern 555.

An inductance of the inductor pattern 532 may be defined by the length of the inductor pattern 532. The inductance of the inductor pattern 532 is a dominant factor in adjusting/controlling the secondary resonance frequency of the multilayer common mode filter 100.

A primary resonance frequency is formed by a capacitance generated among the first coil, the second coil, and the third coil. The secondary resonance frequency is formed by the capacitor patterns 511 to 516, the floating pattern 522, and the inductor pattern 532.

In this case, since the inductor pattern 532 has a relatively large value compared to the capacitance formed between the capacitor patterns 511 to 516 and the floating pattern 522, the inductor pattern 532 is a dominant factor in determining the secondary resonance frequency.

The inductor pattern 532 has, within the same area, a value adjustment range allowing the secondary resonant frequency to be adjusted to various values, and can improve design flexibility due to having a smaller area compared to the capacitor patterns 511 to 516. The capacitor patterns 511 to 516 and the floating pattern 522 form a relatively small capacitance compared to the inductor pattern 532, thereby reducing loss during signal transmission.

As such, the inductor pattern 532 serves as the dominant factor in determining the secondary resonant frequency and can reduce the influence of parasitic inductance (parasitic L) that varies depending on the mounting orientation of a chip, thereby preventing characteristic deviations due to the mounting orientation.

Unlike a conventional multilayer common mode filter configured with a stack including a magnetic layer (ferrite layer), the multilayer common mode filter according to an embodiment of the present disclosure is configured with a low temperature co-fired ceramic (LTCC) stack that does not include a magnetic layer.

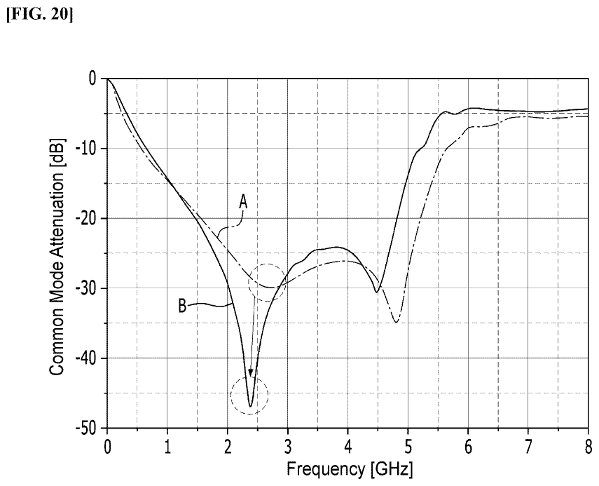

Graph A in FIG. 20 illustrates common mode attenuation characteristics measured from the conventional multilayer common mode filter, and Graph B illustrates common mode attenuation characteristics measured from the multilayer common mode filter according to an embodiment of the present disclosure.

The conventional multilayer common mode filter forms a primary resonance point at approximately 2.70 GHz, and has common mode attenuation characteristics of approximately −29.87 dB at the primary resonance point.

The common mode filter according to an embodiment of the present disclosure forms a primary resonance point at approximately 2.37 GHz, and has common mode attenuation characteristics of approximately −47.06 dB at the primary resonance point.

As such, it can be seen that because the multilayer common mode filter according to an embodiment of the present disclosure does not include a magnetic layer, it is possible to prevent loss caused by a magnetic base material, and thus enhance common mode attenuation characteristics at the primary resonance point.

In general, the multilayer common mode filters are required to have cutoff frequency characteristics of approximately −3 dB.

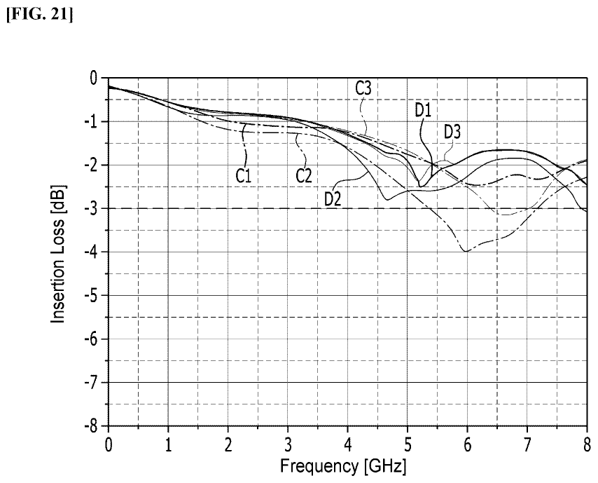

Referring to FIG. 21, in the conventional multilayer common mode filter, an insertion loss C1 between a first channel line and a second channel line is measured to be equal to or greater than −3 dB in all frequency bands, an insertion loss C2 between the first channel line and a third channel line is measured to be less than −3 dB in a frequency band ranging from approximately 5.4 GHz to approximately 7.2 GHz, and an insertion loss C3 between the second channel line and the third channel line is measured to be less than −3 dB in a frequency band of approximately 6.5 GHz.

As such, in the conventional multilayer common mode filter, although the insertion loss C1 between the first channel line and the second channel line is measured to be −3 dB, which is required by the industrial market, in the entire frequency band, the insertion loss C2 between the first channel line and the third channel line and the insertion loss C3 between the second channel line and the third channel line are measured to be −3 dB or less in some frequency bands, and thus fail to satisfy cutoff frequency characteristics required by the industrial market.

On the other hand, in the multilayer common mode filter according to an embodiment of the present disclosure, an insertion loss D1 between the first channel line and the second channel line, an insertion loss D2 between the first channel line and the third channel line, and an insertion loss D3 between the second channel line and the third channel line are reduced compared to those of the conventional multilayer common mode filter, are measured to be equal to or greater than −3 dB in all frequency bands, and it can be seen that cutoff frequency characteristics required by the industrial market are satisfied.

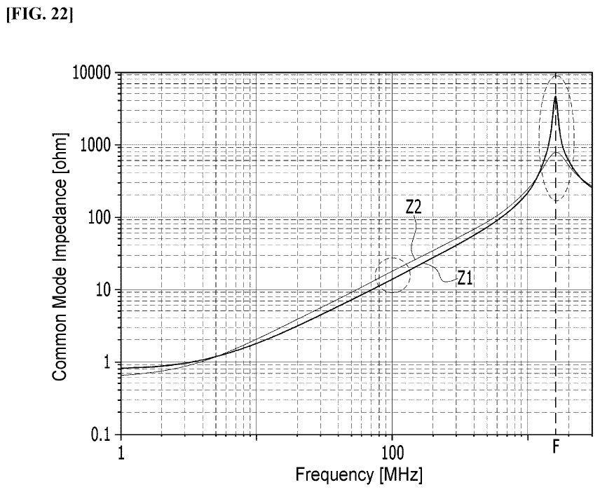

Referring to FIG. 22, common mode impedance Z1 of the multilayer common mode filter according to an embodiment of the present disclosure decreases compared to common mode impedance Z2 of the conventional multilayer common mode filter at a frequency of approximately 100 MHz.

However, at a primary resonance point F, the common mode impedance Z2 of the conventional multilayer common mode filter is measured to be approximately 500 ohms, and the common mode impedance Z1 of the multilayer common mode filter according to an embodiment of the present disclosure is measured to be approximately 5000 ohms.

As described above, it can be seen that because the multilayer common mode filter according to an embodiment of the present disclosure is configured with a low temperature co-fired ceramic stack that does not include a magnetic layer, the multilayer common mode filter has a relatively high Q factor compared to the conventional multilayer common mode filter and, accordingly, the common mode impedance increases at the primary resonance point F.

The above description is merely a description of the technical spirit of the present disclosure, and those skilled in the art may change and modify the present disclosure in various ways without departing from the essential characteristic of the present disclosure. Accordingly, the embodiments described in the present disclosure should not be construed as limiting the technical spirit of the present disclosure, but should be construed as describing the technical spirit of the present disclosure. The technical spirit of the present disclosure is not restricted by the embodiments. The range of protection of the present disclosure should be construed based on the following claims, and all of technical spirits within an equivalent range of the present disclosure should be construed as being included in the scope of rights of the present disclosure.

1. A multilayer common mode filter comprising:
a first stack provided with a plurality of coil patterns;
a second stack provided with a plurality of coil patterns, and disposed under the first stack; and
a third stack disposed under the second stack,
wherein the third stack comprises:
a plurality of capacitor patterns disposed under the second stack;
a floating pattern disposed under the plurality of capacitor patterns, and configured to form additional capacitance by overlapping with the plurality of capacitor patterns;
a ground pattern disposed under the floating pattern; and
an inductor pattern disposed between the floating pattern and the ground pattern, and
wherein a first end of the inductor pattern is connected to the floating pattern, and a second end of the inductor pattern is connected to the ground pattern.

2. The multilayer common mode filter of claim 1, wherein each of the first stack, the second stack, and the third stack comprises a low temperature co-fired ceramic stack.

3. The multilayer common mode filter of claim 1,
where the first stack includes a first coil pattern, a second coil pattern, and a third coil pattern,
wherein the second stack includes a fourth coil pattern, a fifth coil pattern, and a sixth coil pattern,
wherein the first stack and the second stack form a coil stack,
wherein the coil stack is configured such that the first coil pattern, the second coil pattern, the third coil pattern, the fourth coil pattern, the fifth coil pattern, and the sixth coil pattern are sequentially stacked,
wherein the first coil pattern and the sixth coil pattern form a first coil that forms a first channel,
wherein the second coil pattern and the third coil pattern are interposed between the first coil pattern and the sixth coil pattern, and form a second coil that forms a second channel, and
wherein the fourth coil pattern and the fifth coil pattern are interposed between the third coil pattern and the sixth coil pattern, and form a third coil that forms a third channel.

4. The multilayer common mode filter of claim 1, wherein the first stack comprises:
a first sheet;
a first terminal pattern placed on a first surface of the first sheet;
a second terminal pattern placed on the first surface of the first sheet, and spaced apart from the first terminal pattern;
a second sheet disposed under the first sheet;
a first coil pattern forming a first loop that has a rectangular shape and is wound on a first surface of the second sheet, the first coil pattern including a first end positioned in an inner peripheral region of the first loop and connected to the first terminal pattern through a via hole passing through the first sheet, and a second end positioned in an outer peripheral region of the first loop;
a third sheet disposed under the second sheet;
a second coil pattern forming a second loop that has a rectangular shape and is wound on a first surface of the third sheet, the second coil pattern including a first end positioned in an inner peripheral region of the second loop and connected to the second terminal pattern through a via hole passing through the first sheet and the second sheet, and a second end positioned in an outer peripheral region of the second loop;
a fourth sheet disposed under the third sheet; and
a third coil pattern forming a third loop that has a rectangular shape and is wound on a first surface of the fourth sheet, the third coil pattern including a first end positioned in an inner peripheral region of the third loop and connected to the second end of the second coil pattern through a via hole passing through the third sheet, and a second end positioned in an outer peripheral region of the third loop.

5. The multilayer common mode filter of claim 1, wherein the second stack comprises:
a fifth sheet;
a fourth coil pattern forming a fourth loop that has a rectangular shape and is wound on a first surface of the fifth sheet, the fourth coil pattern including a first end positioned in an inner peripheral region of the fourth loop, and a second end positioned in an outer peripheral region of the fourth loop;
a sixth sheet disposed under the fifth sheet;
a fifth coil pattern forming a fifth loop that has a rectangular shape and is wound on a first surface of the sixth sheet, the fifth coil pattern including a first end positioned in an inner peripheral region of the fifth loop and connected to the first end of the fourth coil pattern through a via hole passing through the fifth sheet, and a second end positioned in an outer peripheral region of the fifth loop;
a seventh sheet disposed under the sixth sheet;
a sixth coil pattern forming a sixth loop wound on a first surface of the seventh sheet, the sixth coil pattern including a first end positioned in an inner peripheral region of the sixth loop, and a second end positioned in an outer peripheral region of the sixth loop;
an eighth sheet disposed under the seventh sheet;
a third terminal pattern placed on the first surface of the seventh sheet, and including a first end connected to the first end of the fourth coil pattern and the first end of the fifth coil pattern through a via hole passing through the fifth sheet, the sixth sheet, and the seventh sheet; and
a fourth terminal pattern placed on the first surface of the seventh sheet and spaced apart from the third terminal pattern, the fourth terminal pattern including a first end connected to the first end of the sixth coil pattern through a via hole passing through the seventh sheet.

6. The multilayer common mode filter of claim 1, wherein the third stack comprises:
a ninth sheet;
a plurality of capacitor patterns placed on a first surface of the ninth sheet and spaced apart from each other;
a tenth sheet disposed under the ninth sheet;
a floating pattern placed on a first surface of the tenth sheet, and forming a plurality of overlapping areas by overlapping with the plurality of capacitor patterns, the floating pattern being configured to form additional capacitance in the plurality of overlapping regions;
an eleventh sheet disposed under the tenth sheet;
an inductor pattern forming a seventh loop wound on the first surface of the tenth sheet, the inductor pattern including a first end positioned in an inner peripheral region of the seventh loop and connected to the floating pattern;
a twelfth sheet disposed under the eleventh sheet; and
a ground pattern disposed on a first surface of the twelfth sheet, and connected to a second end of the inductor pattern.

7. The multilayer common mode filter of claim 6, wherein the inductor pattern includes:
a first region overlapping the ground pattern; and
a second region not overlapping the ground pattern.

8. The multilayer common mode filter of claim 1,
wherein a filter stack formed by stacking the first stack, the second stack, and the third stack has a first resonant frequency, and a second resonant frequency higher than the first resonant frequency, and
wherein the second resonant frequency shifts to a higher frequency as a length of the inductor pattern increases.

9. The multilayer common mode filter of claim 1,
wherein a filter stack formed by stacking the first stack, the second stack, and the third stack has a first resonant frequency, and a second resonant frequency higher than the first resonant frequency, and
wherein the second resonant frequency shifts to a lower frequency as a length of the inductor pattern decreases.

10. The multilayer common mode filter of claim 1,
wherein a filter stack formed by stacking the first stack, the second stack, and the third stack includes a first side surface, a second side surface opposite to the first side surface, a third side surface, and a fourth side surface opposite to the third side surface, the multilayer common mode filter further comprising:
a first external electrode disposed on the first side surface, and connected to a second end of a first coil pattern, a second end of a sixth coil pattern, and a third end of a first capacitor pattern that are exposed to the first side surface;
a second external electrode disposed on the first side surface, and connected to a second end of a second coil pattern, a second end of a third coil pattern, and a second end of a second capacitor pattern that are exposed to the first side surface;
a third external electrode disposed on the first side surface, and connected to a second end of a fourth coil pattern, a second end of a fifth coil pattern, and a second end of a third capacitor pattern that are exposed to the first side surface;
a fourth external electrode disposed on the second side surface, and connected to a second end of a first terminal pattern, a second end of a fourth terminal pattern, and a second end of a fourth capacitor pattern that are exposed to the second side surface;
a fifth external electrode disposed on the second side surface, and connected to a second end of a third terminal pattern and a second end of a fifth capacitor pattern that are exposed to the second side surface; and
a sixth external electrode disposed on the second side surface, and connected to a second end of a second terminal pattern and a second end of a sixth capacitor pattern that are exposed to the second side surface.

11. The multilayer common mode filter of claim 10, further comprising:
a seventh external electrode disposed on the third surface, and connected to a first end of a ground pattern that is exposed to the third side surface; and
an eighth external electrode disposed on the fourth side surface, and connected to a second end of the ground pattern that is exposed to the fourth side surface.
